(19) United States
(12) Patent Application Publication
(10) Pub. No.: US 2025/0216739 A1
(43) Pub. Date: Jul. 3, 2025

(54) Light Controlling Panel and Transparent Display Device Including the Same

(71) Applicant: LG Display Co., Ltd., Seoul (KR)

(72) Inventors: SangHyun Lee, Seongnam-si (KR); MinJin Lee, Seoul (KR); MinSoo Park, Anyang-si (KR)

(21) Appl. No.: 18/769,879

(22) Filed: Jul. 11, 2024

(30) Foreign Application Priority Data
Dec. 29, 2023 (KR) 10-2023-0197837

(51) Int. Cl. G02F 1/1681; G02F 1/167; G02F 1/16761; G02F 1/1685; H10K 59/50

(52) U.S. Cl. CPC G02F 1/1681; G02F 1/167; G02F 1/16761; G02F 1/1685; H10K 59/50

(57) ABSTRACT

A light controlling panel includes a first electrode and a second electrode that face each other, and a dielectric layer and charged particles between the first electrode and the second electrode. The dielectric layer comprises a dielectric material having a dielectric constant and includes a groove and a spacer. The first electrode includes a plurality of block electrodes that are divided into a plurality of blocks and are individually driven.

### CROSS-REFERENCE TO RELATED APPLICATION

This application claims the priority of Republic of Korea Patent Application No. 10-2023-0197837 filed on Dec. 29, 2023, which is hereby incorporated by reference in its entirety.

### BACKGROUND

### Field

The present disclosure relates to a light controlling panel and a transparent display device including the same. More particularly, the present disclosure relates to a light controlling panel capable of improving picture quality characteristics by increasing transmittance and a shield rate, and a transparent display device including the same.

### Description of the Related Art

With the development of information society, the demand for a display device for displaying an image is increasing in various forms. Accordingly, recently, several display devices, such as a liquid crystal display (LCD), a plasma display panel (PDP), a quantum dot light emitting display (QLED), and an organic light emitting display (OLED), have been used.

In particular, the organic light emitting display device are not only advantageous in terms of power consumption due to low voltage driving, but also have excellent color reproduction, response speed, viewing angle, and contrast ratio, and therefore, are in the spotlight as a next-generation display.

Recently, researches are being actively conducted on a transparent display device of which some areas include a transmissive area to allow external light to transmit, thereby allowing objects or images located in backgrounds or on the other side of the display device to be viewed. Researches are being conducted on a light control device to control light transmittance or reflectance by applying the light control device to such transparent display device or image display device.

### SUMMARY

An object to be achieved by the present disclosure is to provide a light controlling panel capable of selectively improving display definition through a light blocking mode that blocks light and allows backgrounds of the display panel to be visible through a transmissive mode that transmits light, and a transparent display device including the same.

In addition, another object to be achieved by the present disclosure is to provide a light controlling panel capable of improving light transmittance in a transmissive mode and a transparent display device including the same.

In addition, still another object to be achieved by the present disclosure is to provide a transparent display panel capable of implementing environment/social/governance (ESG) by increasing a lifespan of a display device to reduce a generation of greenhouse gases that may be generated during a manufacturing process for producing a new display device, and a display device.

Objects of the present disclosure are not limited to the above-mentioned objects, and other objects, which are not mentioned above, can be clearly understood by those skilled in the art from the following descriptions.

According to an embodiment of the present disclosure, a light controlling panel includes a first electrode and a second electrode disposed to face each other; and a dielectric layer and charged particles provided between the first electrode and the second electrode,
wherein the dielectric layer is provided with one or more grooves, and the dielectric layer has a dielectric pattern disposed between adjacent grooves and a plurality of spacers protruding toward the second electrode on a portion of a top surface of the dielectric pattern.

According to another embodiment of the present disclosure, a light controlling panel includes a first electrode and a second electrode that face each other, and a dielectric layer between the first electrode and the second electrode, the dielectric layer including a first dielectric layer that comprises a first dielectric material having a first dielectric constant and includes grooves and a second dielectric layer that comprises a plurality of light blocking particles and a solvent that comprises a second dielectric material having a second dielectric constant smaller than the first dielectric constant, and the first dielectric has a dielectric pattern between adjacent grooves and a spacer protruding toward the second electrode on a portion of a top surface of the dielectric pattern. The groove may have a stripe shape.

According to still another embodiment of the present disclosure, a transparent display device includes a transparent display panel including a transmissive area through which external light is transmitted and a non-transmissive area where a plurality of pixels are disposed; a first electrode and a second electrode disposed to face each other; and a dielectric layer and charged particles provided between the first electrode and the second electrode, wherein the dielectric layer is provided with one or more grooves, and wherein the dielectric layer has a dielectric pattern disposed between adjacent grooves and a plurality of spacers protruding toward the second electrode on a portion of a top surface of the dielectric pattern.

According to still another embodiment of the present disclosure, a transparent display device includes a transparent display panel including a transmissive area through which external light is transmitted and a non-transmissive area that includes a plurality of pixels and a light controlling panel including a first electrode, a second electrode, and a dielectric layer between the first electrode and the second electrode, the dielectric layer including a first dielectric layer that comprises a first dielectric material having a first dielectric constant and includes grooves and a second dielectric layer that includes a plurality of light blocking particles and a solvent that includes a second dielectric material having a second dielectric constant smaller than the first dielectric constant, and the first dielectric has a spacer protruding toward the second electrode disposed between the adjacent grooves. The groove may have a stripe shape. The first electrode may have a stripe shape while intersecting the groove.

A top surface of the spacer may be coated with a black resin.

According to the light controlling panel and transparent display device of the present disclosure, it is possible to selectively implement the light blocking mode and the transmissive mode. As a result, according to the transparent display device of the present disclosure, by allowing the user to clearly see the objects and the background located on the back surface of the transparent display device in the transmissive mode and at the same time blocking the external light from penetrating into the transparent display device in the light blocking mode, it is possible to provide the image with the high contrast ratio to the user.

According to the light controlling panel and transparent display device of the present disclosure, the light controlling panel may be separated to form the plurality of unit cells and separately drive each unit cell, thereby controlling the transmittance for each area.

In addition, according to the light controlling panel and transparent display device of the present disclosure, the first dielectric may have the groove, so the plurality of light blocking particles may move into the groove and may not remain on the top surface of the first dielectric during the transmissive mode. As a result, according to the light controlling panel and transparent display device of the present disclosure, it is possible to increase the light transmittance in the transmissive mode.

In addition, according to the light controlling panel and transparent display device of the present disclosure, each of the plurality of unit cells of the light controlling panel includes the lower electrode and the upper electrode, and the lower electrode may include the patterning electrode. As a result, when operating in the transmissive mode, the light blocking particles may move to the groove where the patterning electrode is formed not to remain on the top surface of the first dielectric. As a result, according to the optical control panel and transparent display device of the present disclosure, it is possible to maximize the light transmittance in the transmissive mode.

In addition, according to the light controlling panel and transparent display device of the present disclosure, the spacer of the first dielectric is disposed to overlap the non-transmissive area of the transparent display panel, so, when the transparent display device operates in the transmissive mode, the light transmittance of the transparent display device may be suppressed from deteriorating due to the spacer.

In addition, according to the light controlling panel and transparent display device of the present disclosure, by adjusting the magnitude of the voltage applied to the upper and lower electrodes for each area, it is possible to vary the transmittance for each area.

In addition, according to the light controlling panel and transparent display device of the present disclosure, by forming the first dielectric to have the predetermined thickness in the area where the groove is formed, it is possible to alleviate the impact of the light blocking particles as the light blocking particles are collected in the groove. As a result, according to the light controlling panel and transparent display device of the present disclosure, it is possible to suppress the light blocking particles from being damaged. In addition, according to the light controlling panel and transparent display device of the present disclosure, by making the dielectric constant difference between the first dielectric and the second dielectric large, it is possible to allow the plurality of light blocking particles to completely enter the groove of the first dielectric.

In addition, according to the light controlling panel and transparent display device of the present disclosure, by simultaneously forming the dielectric pattern, the spacer, and the groove through the imprinting process, it is possible to reduce the manufacturing process costs and simplify the manufacturing process to shorten the manufacturing process time, and furthermore, reduce the production energy. In addition, according to the light controlling panel and transparent display device of the present disclosure, by reducing the manufacturing process to reduce the generation of greenhouse gases that may be generated by the manufacturing process, it is possible to implement the environment/social/governance (ESG).

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view schematically illustrating a transparent display device according to an embodiment of the present disclosure;

FIG. 2 is a plan view of the transparent display panel according to an embodiment of the present disclosure;

FIG. 3 is a diagram illustrating an example of a transmissive area and a non-transmissive area provided in a display area of FIG. 2 according to an embodiment of the present disclosure;

FIG. 4 is a circuit diagram of a sub-pixel of FIG. 3 according to an embodiment of the present disclosure;

FIG. 5 is a cross-sectional view taken along line I-I′ of FIG. 3 according to an embodiment of the present disclosure;

FIG. 6 is a perspective view of a light controlling panel according to a first embodiment of the present disclosure;

FIG. 7A is a cross-sectional view of a light controlling panel according to the first embodiment of the present disclosure;

FIGS. 7B to 7D are cross-sectional views of the light controlling panel of FIG. 7A in the light blocking mode according to the first embodiment of the present disclosure;

FIGS. 8A to 8C are cross-sectional views of the light controlling panel in a transmissive mode according to the first embodiment of the present disclosure;

FIGS. 9A and 9B are cross-sectional views of a light controlling panel in a light blocking mode according to a second embodiment of the present disclosure;

FIGS. 10A to 10C are diagrams illustrating a light controlling panel and a transparent display device in a transmissive mode according to the second embodiment of the present disclosure;

FIG. 11A is a perspective view of a light controlling panel according to a third embodiment of the present disclosure;

FIGS. 11B and 11C are diagrams illustrating the light controlling panel and the transparent display device in the transmissive mode according to the third embodiment of the present disclosure;

FIGS. 12A to 12C are perspective views comparing transmittance when different voltages are applied according to an embodiment of the present disclosure; and

FIG. 13 is a diagram of varying transmission for each area of a light controlling panel according to an embodiment of the present disclosure.

### DETAILED DESCRIPTION

When the relation of a time sequential order is described using the terms such as “after”, “continuously to”, “next to”, and “before”, the order may not be continuous unless the terms are used with the term “immediately” or “directly”.

In describing components of the embodiment of the present disclosure, terminologies such as first, second, A, B, (a), (b), and the like may be used. These terminologies are used to distinguish a component from the other component, but a nature, an order, or the number of the components is not limited by the terminology. When a component is “linked”, “coupled”, or “connected” to another component, the component may be directly linked or connected to the other component. However, unless specifically stated otherwise, it should be understood that a third component may be interposed between the components which may be indirectly linked or connected.

It should be understood that “at least one” includes all combinations of one or more of associated components. For example, “at least one of first, second, and third components” means that not only a first, second, or third component, but also all combinations of two or more of first, second, and third components are included.

In the present specification, a “display apparatus” may include a display apparatus which includes a display panel and a driver for driving the display panel, in a narrow sense, such as a liquid crystal module (LCM), inorganic light emitting module (LED module), an organic light emitting module (OLED module), and a quantum dot module. Further, the “display apparatus” may further include a set electronic apparatus or a set apparatus (or a set device) which is a complete product or a final product including an LCM, an OLED module, a quantum dot (QD) module, etc., such as a notebook computer, a television, or a computer monitor, an automotive display apparatus or equipment display apparatus including another type of vehicle and a mobile electronic apparatus including a smart phone or an electronic pad.

Accordingly, the display apparatus of the present disclosure may include not only a display apparatus itself in a narrow sense such as an LCM, an OLED module, a QD module, etc., but also an applied product or a set apparatus which is a final consumer device including the LCD, the OLED module, the QD module, etc.

Further, in some cases, the LCM, the OLED module, or the QD module which is configured by a display panel and a driver may be represented as “a display apparatus” in a narrow sense and an electronic device as a complete product including the LCM, the OLED module, and the QD module may be represented as a “set apparatus”. For example, the display apparatus in the narrow sense includes a liquid crystal (LCD) display panel, an OLED display panel, or a quantum dot display panel and a source printed circuit board (PCB) which is a controller for driving the display panel. In contrast, the set apparatus may be a concept further including a set PCB which is a set controller which is electrically connected to the source PCB to control the entire set apparatus.

As a display panel used in the embodiment of the present disclosure, any type of display panel such as a liquid crystal display panel, an organic light emitting diode (OLED) display panel, a quantum dot (QD) display panel, and an electroluminescent display panel may be used. The display panel of the present embodiment is not limited to a specific display panel in which a bezel is bent with a flexible substrate for the organic light emitting diode (OLED) display panel and a back plate support structure there below. Further, a display panel used for the display apparatus according to the embodiment of the present disclosure is not limited to a shape or a size of the display panel.

For example, when the display panel is an OLED display panel, the display panel may include a plurality of gate lines, data lines, and pixels formed at intersecting areas of the gate lines and/or data lines. Further, the display panel may be configured to include an array including a thin film transistor which is an element to selectively apply a voltage to each pixel, a light emitting diode layer on the array, an encapsulation substrate or an encapsulation layer, and the like disposed on the array so as to cover the light emitting diode layer. The encapsulation layer may protect the thin film transistor the light emitting diode layer, and the like from external impacts and may suppress the permeation of moisture or oxygen into the light emitting diode layer. Further, a layer formed on the array may include an inorganic light emitting layer, for example, a nano-sized material layer quantum dots, or the like.

The features of various embodiments of the present disclosure can be partially or entirely coupled to or combined with each other and can be interlocked and operated in technically various ways, and the embodiments can be carried out independently of or in association with each other.

Hereinafter, the embodiment of the present disclosure will be described with reference to the accompanying drawings and embodiments as follows. Scales of components illustrated in the accompanying drawings are different from the real scales for the purpose of description, so that the scales are not limited to those illustrated in the drawings.

Hereinafter, an embodiment of the present disclosure will be described in detail with reference to the drawings.

Hereinafter, embodiments of the present specification will be described in detail with reference to the drawings. Embodiments to be provided below are provided by way of example so that the spirit of the present disclosure may be sufficiently transferred to those skilled in the art. Accordingly, the present disclosure is not limited to the embodiments described below, and may be implemented in various different forms.

In addition, in the accompanying drawings, widths, lengths, thicknesses, and the like, of devices may be exaggerated for convenience. The scale of the components illustrated in the drawings is different from the actual scale for convenience of description, and therefore, is not limited to that illustrated in the drawings. Same reference numerals denote same constituent elements throughout the specification.

Further, when it is determined that a detailed description of the known art related to the present disclosure may obscure the gist of the present disclosure, the detailed description thereof will be omitted.

Other parts may be added when “include,” “have,” “composed,” “comprise,” etc., are used as described in the present disclosure. When a component is expressed in the singular, it may include a case in which the plural is included unless otherwise explicitly stated.

In the case of a description of a positional relationship, for example, when the positional relationship between two parts is described as “on,” “over,” “below,” “next to,” etc., unless “immediately” or “directly” is used, one or more other parts may be located between two parts. Spatially relative terms “below,” “beneath,” “lower,” “above,” “upper,” and the like may be used to easily describe the correlation between one element or components and other elements or components as illustrated in the drawings. The spatially relative terms should be understood as terms including different directions of elements during use or operation in addition to the directions illustrated in the drawings. For example, when elements illustrated in the drawings are turned up, an element described as “below” or “beneath” another component may be disposed “above” the another component. Therefore, the term “below” may include both downward and upward directions.

The terms first, second, A, B, (a), (b), and the like may be used in describing components of the present disclosure. These terms are used only in order to distinguish the components from other components, and the nature, sequence, order, number, or the like, of the corresponding components are not limited by these terms.

In adding reference numerals to components of each drawing, the same components will be denoted by the same reference numerals even though they are illustrated in different drawings. Further, in describing the present disclosure, well-known functions or constructions will not be described in detail since they may unnecessarily obscure the gist of the present disclosure.

Each feature of various embodiments of the present disclosure may be partially or fully coupled or combined with each other, and enable various technological links and operations, and each embodiment may be implemented independently of each other or may be implemented together in the related relationship.

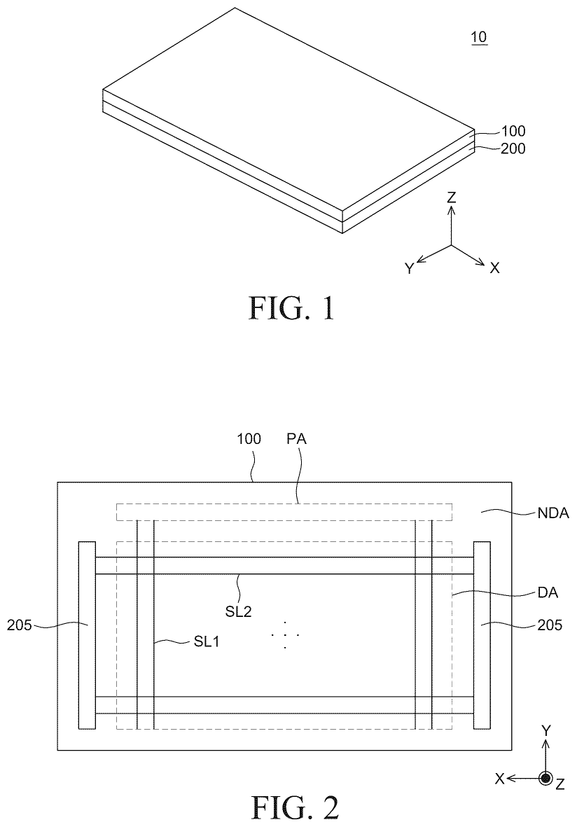

Hereinafter, embodiments of the present disclosure will be described through the accompanying drawings and embodiments. FIG. 1 is a perspective view of a transparent display device according to an embodiment of the present disclosure.

In FIGS. 1 and 2, an X-axis represents a direction parallel to a gate line, a Y-axis represents a direction parallel to a data line, and a Z-axis represents a height direction of a display device.

A display device 10 according to an embodiment of the present disclosure will be described with a focus on being implemented as an organic light emitting display, but may also be implemented as an inorganic light emitting display, a liquid crystal display or a plasma display panel (PDP), a quantum dot light emitting display (QLED), or an electrophoresis display.

Referring to FIG. 1, the transparent display device 10 according to an embodiment of the present disclosure includes a transparent display panel 100 and a light controlling panel 200. In the display panel 100, a display area and a non-display area disposed in the vicinity of the display area, surrounding the display area, or around the display area may be defined.

The transparent display panel 100 includes a plurality of pixels to display an image. At least some areas of the transparent display panel 100 may be provided with a transmissive area that allows most of light incident from the outside to transmit. The transparent display panel 100 may have the transmissive area between a plurality of pixels. The transparent display panel 100 allows external objects or backgrounds to be visible due to the transmissive areas.

The light controlling panel 200 may be disposed on at least one surface of the transparent display panel 100 and may control light incident on the transparent display panel 100. The light controlling panel 200 may include ink containing charged particles that move by an electric field. The light controlling panel 200 may implement a light blocking mode and a transmissive mode by controlling the movement of the ink containing the charged particles. Depending on a voltage applied to the ink containing the charged particles, the light blocking mode may be converted into the transmissive mode or the transmissive mode may be converted into the light blocking mode. The light controlling panel 200 may block incident light in the light blocking mode and transmit incident light in the transmissive mode.

It is preferable that the light controlling panel 200 is disposed in a direction opposite to a direction in which the transparent display panel 100 emits light. For example, when the transparent display panel 100 is a top emission type, the light controlling panel 200 may be disposed below the transparent display panel 100 as illustrated in FIG. 1. As another example, when the transparent display panel 100 is a bottom emission type, the light controlling panel 200 may be disposed on the transparent display panel 100.

The light controlling panel 200 may be attached to one surface of the transparent display panel 100 using an adhesive layer (not illustrated). The adhesive layer (not illustrated) may be a transparent adhesive film such as optically clear adhesive (OCA) or a transparent adhesive such as optically clear resin (OCR).

In FIG. 1, the light controlling panel 200 is illustrated as being disposed on one surface exposed to the outside of the transparent display panel 100, but is not necessarily limited thereto. The light controlling panel 200 may be disposed within the transparent display panel 100. In this case, the light controlling panel 200 may be disposed on a top surface of one of a plurality of layers provided in the transparent display panel 100. As an example, the light controlling panel 200 may be provided between a substrate and a transistor of the transparent display panel 100. In this case, the light controlling panel 200 may not be provided with a separate substrate.

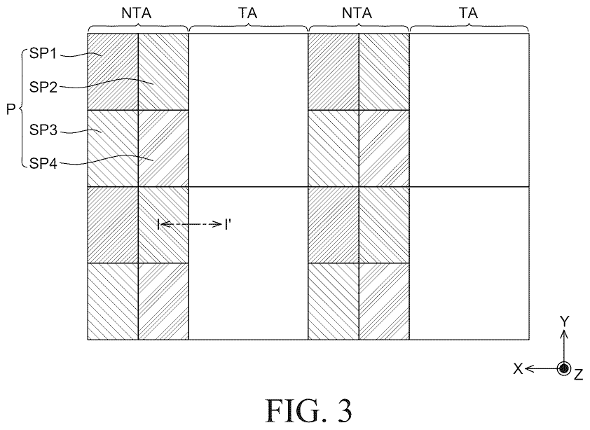

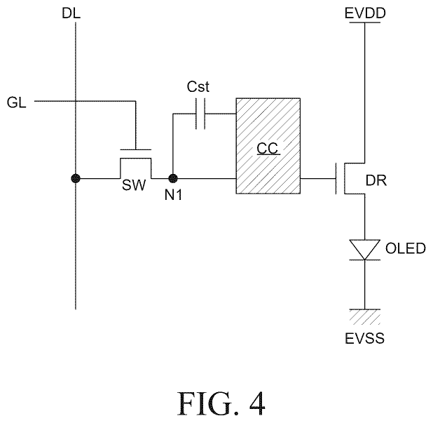

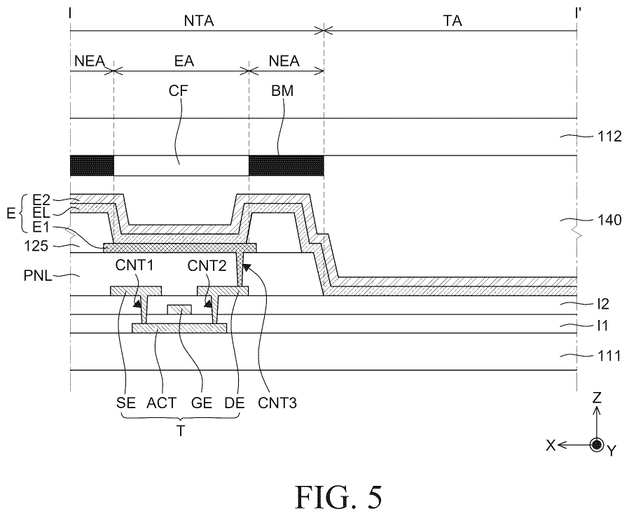

Hereinafter, the transparent display panel 100 will be described in more detail with reference to FIGS. 2 to 4. FIG. 2 is a plan view of the transparent display panel according to an embodiment of the present disclosure, FIG. 3 is a diagram illustrating an example of a transmissive area and a non-transmissive area provided in a display area of FIG. 2 according to an embodiment of the present disclosure, FIG. 4 is a circuit diagram of a sub-pixel according to an embodiment of the present disclosure, and FIG. 5 is a cross-sectional view taken along line I-I′ of FIG. 3 according to an embodiment of the present disclosure.

Referring to FIGS. 2 to 5, the transparent display panel 100 according to the embodiment of the present disclosure may be divided into a display area DA in which pixels P are formed to display images, and a non-display area NDA in which images is not displayed.

The display area DA may be provided with first signal lines SL1, second signal lines SL2, and pixels P. The non-display area NDA may include a pad area PA where pads are disposed and at least one scan driver 205. But components of the display device of the present disclosure are not limited thereto. For example, the display device may also include a data driver and a timing controller for controlling the scan driver and the data driver. Meanwhile, all the components of each display device according to all embodiments of the present disclosure are operatively coupled and configured.

The data driver (not shown) may convert image data received from the timing controller into gamma compensation voltages in response to a data control signal provided from the timing controller and output data voltages. The data voltages output from the data driver may be supplied to the data lines DL. The data driver may be configured with at least one data IC. In this case, as an example, the data IC of the data driver may be connected to non-display area on a corresponding one side of the display panel 100, or may be mounted directly on the non-display area. As an example, the data IC of the data driver may be mounted on a flexible circuit film and connected to the non-display area on a corresponding one side of the display panel 100.

The timing controller may align image data input from the outside and supply the aligned image data to the data driver. The timing controller may generate the gate control signal and the data control signal based on timing signals synchronized with the input image signal, such as a dot clock signal, a data enable signal, and horizontal/vertical synchronization signals. Here, the horizontal synchronization signal is a signal representing a time taken to display one horizontal line of a screen and the vertical synchronization signal is a signal representing a time taken to display a screen of one frame. The data enable signal may correspond to a signal indicating a period for which a data voltage is supplied to the pixel. The timing controller may control operation timings of the scan driver and the data driver by supplying the gate control signal to the scan driver and supplying the data control signal to the data driver.

The first signal lines SL1 and the pixels P may be disposed to extend in a first direction (e.g., Y-axis direction) in the display area DA. For example, the first signal lines SL1 may be data lines, but are not necessarily limited thereto. The first signal lines SL1 may include at least one of a pixel power line, a common power line, and a reference line.

The second signal lines SL2 may extend in a second direction (e.g., X-axis direction) in the display area DA, and may intersect the first signal lines SL1 in the display area DA. For example, the second signal lines SL2 may be scan lines, but are not necessarily limited thereto.

The scan driver 205 is connected to a scan line to supply scan signals. This scan driver 205 may be formed in the non-display area NDA outside one or both sides of the display area DA of the transparent display panel 100 using a gate driver in panel (GIP) type or a tape automated bonding (TAB) type.

The scan driver 205 may supply scan signals to scan lines SL in response to a gate control signal provided from the timing controller (not shown). The scan driver 205 may be disposed in at least a non-display area NDA of the display panel 100 as shown in FIG. 2 or disposed in a display area DA. Even though in FIG. 2, it is illustrated that two scan drivers 205 are disposed at two sides of the display panel 100, the number of the scan driver 205 and the placement thereof are not limited thereto. For example, one scan driver 205 may be disposed at one side of the display panel 100. For example, the gate drivers 120 may be mounted on the display panel 100. As such, the structure in which the scan driver 205 is directly mounted on the display panel 100 is referred to as a gate in panel (GIP) structure, without being limited thereto. Alternatively, the scan driver 205 120 may be spaced apart from the display panel 100.

The display area DA includes a transmissive area TA and a non-transmissive area NTA, as illustrated in FIG. 3. The transmissive area TA is an area that transmits most of light incident from the outside, and the non-transmissive area NTA is an area that does not transmit most of light incident from the outside. For example, the transmissive area TA may be an area where light transmittance is greater than α%, and the non-transmissive area NTA may be an area where the light transmittance is less than β%. In this case, α is a value greater than β. The transparent display device 10 may view objects or backgrounds located on a back surface of the transparent display device 10 due to the transmissive area TAs of the transparent display panel 100.

The non-transmissive area NTA includes an emission area EA in which a plurality of pixels P are provided and emit light. A plurality of pixel regions may be arranged in a matrix form along a plurality of row and column lines. The plurality of pixel regions may include pixel regions displaying different colors, for example, red (R), green (G), and blue (B), or red (R), green (G), blue (B), and white (W). At this time, the red (R), green (G), and blue (B) pixel regions that are adjacent to each other or the red (R), green (G), blue (B), and white (W) pixel regions that are adjacent to each other may function as a unit pixel for displaying a color image. Each of the plurality of pixels P may include a first sub-pixel SP1, a second sub-pixel SP2, a third sub-pixel SP3, and a fourth sub-pixel SP4. The first sub-pixel SP1 may include a first emission area EA that emits first color light, and the second sub-pixel SP2 may include a second emission area EA that emits second color light. The third sub-pixel SP3 may include a third emission area EA that emits third color light, and the fourth sub-pixel SP4 may include a fourth emission area EA that emits fourth color light.

For example, the first to fourth emission areas EA may all emit light of different colors. For example, the first emission area EA may emit green light, and the second emission area EA may emit red light. The third emission area EA may emit blue light, and the fourth emission area EA may emit white light. For example, the first emission area EA may emit blue light, and the second emission area EA may emit green light, the third emission area EA may emit red light, and the fourth emission area EA may emit white light. However, the present disclosure is not limited thereto. In addition, a disposition order of each sub-pixel SP1, SP2, SP3, and SP4 may change in various ways.

For example, the plurality of sub pixels SP may include red, green, and blue sub-pixels, in which the red, green, and blue sub-pixels may be disposed in a repeated manner. Alternatively, the plurality of sub pixels SP may include red, green, blue, and white sub-pixels, in which the red, green, blue, and white sub-pixels may be disposed in a repeated manner, or the red, green, blue, and white sub-pixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the sub-pixels are not limiting, and may be configured in various forms according to light-emitting characteristics, device lifespans, and device specifications.

Meanwhile, the sub-pixels may have different light-emitting areas according to light-emitting characteristics. For example, a sub-pixel that emits light of a color different from that of a blue sub-pixel may have a different light-emitting area from that of the blue sub-pixel. For example, the red sub-pixel, the blue sub-pixel, and the green sub-pixel, or the red sub-pixel, the blue sub-pixel, the white sub-pixel, and the green sub-pixel may each has a different light-emitting area.

Referring to FIG. 4, each of the first to fourth sub-pixels SP1, SP2, SP3, and SP4 may include a switching transistor SW, a driving transistor DR, a capacitor Cst, a compensation circuit CC, and an organic light emitting diode (OLED).

The switching transistor SW transmits a data signal supplied through a data line DL to a first node N1 in response to a scan signal supplied through a gate line GL (or scan line). The capacitor Cst is electrically connected to the first node N1 to charge a voltage applied to the first node N1. The driving transistor DR may control the amount of driving current flowing in the organic light emitting diode (OLED) in response to the voltage applied to the gate electrode.

A semiconductor layer of the switching transistor SW or/and the driving transistor DR may be formed of a semiconductor material, such as an oxide semiconductor, amorphous semiconductor, or polycrystalline semiconductor, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si) or low-temperature poly-Si, but is not limited thereto.

The amorphous semiconductor material may be made of amorphous silicon (a-Si), but is not limited thereto.

The organic light emitting diode (OLED) outputs light corresponding to a driving current. The organic light emitting diode (OLED) may output light corresponding to any one of red, green, and blue. The organic light emitting diode (OLED) may include an anode electrode, a light emitting layer formed on the anode electrode, and a cathode electrode supplying a common voltage. The light emitting layer may be implemented to emit light of the same color for each pixel, such as white light, or may be implemented to emit different colors for each pixel, such as red, green, or blue light, but is not limited thereto.

The compensation circuit CC may be provided in a pixel to compensate for a threshold voltage, etc., of the driving transistor DR. The compensation circuit CC may be composed of one or more transistors. The compensation circuit CC may include one or more transistors and a capacitor, and may be configured in various ways depending on the compensation method. The pixel including the compensation circuit CC may have various structures such as 3T1C, 4T2C, 5T2C, 6T1C, 6T2C, 7T1C, and 7T2C.

FIG. 5 is a cross-sectional view taken along line I-I′ of FIG. 3 according to an embodiment of the present disclosure. Referring to 5, the transparent display panel 100 according to an embodiment of the present disclosure includes the first substrate 111 (or lower substrate) and the second substrate 112 (or upper substrate) facing each other, and may be provided with a light emitting element E including a transistor T, a lower electrode E1, an organic layer EL, and an upper electrode E2 between the lower substrate 111 and the upper substrate 112.

The transistor T includes an active layer ACT provided on the lower substrate 111, a first insulating film I1 provided on the active layer ACT, a gate electrode GE provided on the first insulating film I1, a second insulating film 12 provided on the gate electrode GE, and a source electrode SE and a drain electrode DE provided on the second insulating film 12 and connected to the active layer ACT through first and second contact holes CNT1 and CNT2. In FIG. 5, the transistor T is illustrated as being formed in a top gate manner but is not limited thereto, and may be formed in a bottom gate manner in which the gate electrode GE is disposed below the active layer ACT.

A planarization film PNL may be provided on the transistor T and planarize steps caused by the transistor T and the plurality of signal lines. The planarization film PNL is provided in the non-transmissive area NTA and may not be provided in at least a portion of the transmissive area TA. The planarization film PNL may impair transparency by causing refraction of light as the light is transmitted. Accordingly, the transparent display panel 100 according to the embodiment of the present disclosure may increase transparency by removing a portion of the planarization film PNL from the transmissive area TA.

Meanwhile, in FIG. 5, the first and second insulating films I1 and I2 provided below the planarization film PNL are illustrated as being provided not only in the non-transmissive area NTA but also in the transmissive area TA, but are not necessarily limited thereto. In another embodiment of the present disclosure, some of the insulating films provided below the planarization film PNL may not be provided in at least a portion of the transmissive area TA to increase transparency. For example, the second insulating film I2 is provided in the non-transmissive area NTA and may not be provided in at least a portion of the transmissive area TA.

The light emitting element E including a lower electrode E1, an organic layer EL, and an upper electrode E2 and a bank 125 may be provided above the planarization film PNL.

The lower electrode E1 is provided for each sub-pixel SP1, SP2, SP3, and SP4 on the planarization film PNL, and may not be provided in the transmissive area TA. The lower electrode E1 may be electrically connected to the transistor T. Specifically, the lower electrode E1 may be connected to one of the source electrode SE and the drain electrode DE of the transistor T through the third contact hole CNT3 penetrating through the planarization film PNL. The bank 125 is provided between adjacent lower electrodes E1, so adjacent lower electrodes E1 may be electrically insulated from each other.

The lower electrode E1 may be formed of metal materials with high reflectance such as a laminated structure of aluminum and titanium (Ti/Al/Ti), a laminated structure of aluminum and ITO (ITO/Al/ITO), an Ag alloy, a laminated structure (ITO/Ag alloy/ITO) of Ag alloy and ITO, a MoTi alloy, and a laminated structure (ITO/MoTi alloy/ITO) of MoTi alloy and ITO. The Ag alloy may be an alloy of silver (Ag), palladium (Pd), copper (Cu), etc. The MoTi alloy may be an alloy of molybdenum (Mo) and titanium (Ti). This lower electrode E1 may be referred to as an anode electrode.

The bank 125 may be provided on the planarization film PNL. The bank 125 may be formed of an opaque material to reduce color mixture between the plurality of sub pixels SP and for example, may be formed of black resin, but is not limited thereto. In addition, the bank 125 may be formed to cover an edge of the lower electrode E1 and expose a portion of the lower electrode E1. Accordingly, the bank 125 may suppress the problem of decreasing luminous efficiency due to the concentration of current at an end of the lower electrode E1.

The organic layer EL may be provided on the lower electrode E1. The organic layer EL may include a hole transporting layer, a light emitting layer, and an electron transporting layer. In this case, when the voltage is applied to the lower electrode E1 and the upper electrode E2, holes and electrons move to the light emitting layer through the hole transporting layer and electron transporting layer, respectively, and combine with each other in the light emitting layer to emit light. In an embodiment of the present disclosure, the organic layer EL may be a common layer commonly formed in sub-pixels SP1, SP2, SP3, and SP4. In this case, the light emitting layer may be a white light emitting layer that emits white light. In another embodiment of the present disclosure, the light emitting layer of the organic layer EL may not be formed in the transmissive area TA.

The upper electrode E2 may be provided on the organic layer EL and the bank 125. The upper electrode E2 may be formed of a transparent conductive material (TCO) such as ITO or IZO that may transmit light, or may be formed of a semi-transmissive conductive material such as magnesium (Mg), silver (Ag), or an alloy of magnesium (Mg) and silver (Ag). When the upper electrode E2 is formed of the semi-transmissive conductive material, light output efficiency may increase due to a micro cavity. Th upper electrode E2 may be referred to as a cathode electrode.

An encapsulation layer 140 or encapsulation film 140 may be provided on the light emitting elements E. The encapsulation layer 140 or encapsulation film 140 may be formed on the upper electrode E2 to cover the upper electrode E2. The encapsulation layer 140 or encapsulation film 140 serves to suppress oxygen or moisture from penetrating into the organic layer EL and the upper electrode E2. To this end, the encapsulation layer 140 or encapsulation film 140 may include at least one inorganic film and at least one organic film. When the organic film and the inorganic film are stacked in multiple layers, a movement path of moisture or oxygen may be longer than that of a single layer, thereby effectively blocking the permeation of moisture and oxygen affecting the light emitting layer.

The encapsulation layer 140 may include a first encapsulation layer, a second encapsulation layer, and a third encapsulation layer. The first encapsulation layer to the third encapsulation layer may be sequentially stacked on the upper electrode E2, the first encapsulation layer and the third encapsulation layer may be formed of an inorganic film layer including an inorganic material, and the second encapsulation layer may be formed of an organic film layer including an organic material.

The first encapsulation layer may be formed at the lowermost end of the encapsulation layer 140 to be in contact with the upper surface of the upper electrode E2. The first encapsulation layer may be formed of a material such as silicon nitride SiNx, silicon oxide SiOx, silicon oxynitride SiON, or aluminum oxide A12O3.

The second encapsulation layer may be formed on the first encapsulation layer. The second encapsulation layer may be formed of a material such as acrylic resin, epoxy resin, polyimide, polyethylene PE, or silicon oxycarbon SiOC.

The third encapsulation layer may be formed on the second encapsulation layer. The third encapsulation layer may be formed of the same material as the first encapsulation layer, but not limited thereto, the third encapsulation layer may be formed of different material from the first encapsulation layer.

Meanwhile, the encapsulation layers are not limited to three layers, for example, n layers alternately stacked between inorganic encapsulation layer and organic encapsulation layer (where n is an integer greater than 3) may be included.

A color filter CF may be provided on one surface of the upper substrate 112 facing the lower substrate 111. The color filter CF may be patterned for each sub-pixel SP1, SP2, SP3, and SP4.

Specifically, the color filter CF may include a first color filter, a second color filter, a third color filter, and a fourth color filter. The first color filter may be disposed to correspond to the emission area EA of the first sub-pixel SP1. For example, the first color filter may be a green color filter that transmits green light. The second color filter may be disposed to correspond to the emission area EA of the second sub-pixel SP2 and may be a red color filter that transmits red light. The third color filter CF3 may be disposed to correspond to the emission area EA of the third sub-pixel SP3 and may be a blue color filter that transmits blue light. The fourth color filter may be disposed to correspond to the emission area EA of the fourth sub-pixel SP4 and may be a white color filter that transmits white light. The white color filter may be formed of a transparent organic material that transmits white light, but is not necessarily limited thereto.

A light blocking layer BM may be provided between the color filters CF. The light blocking layer BM may be provided between the sub-pixels SP1, SP2, SP3, and SP4 to suppress color mixing from occurring between adjacent sub-pixels SP1, SP2, SP3, and SP4. In addition, the light blocking layer BM may suppress light incident from the outside from being reflected on a plurality of signal lines provided between the sub-pixels SP1, SP2, SP3, and SP4.

In addition, the light blocking layer BM may be provided between the transmissive area TA and the plurality of sub-pixels SP1, SP2, SP3, and SP4 to suppress the light emitted from each of the plurality of sub-pixels SP1, SP2, SP3, and SP4 from being transmitted to the transmissive area TA. In an embodiment of the present disclosure, the light blocking layer BM may not be provided between a white sub-pixel and the transmissive area TA. The display panel 100 according to the embodiment of the present disclosure does not include the light blocking layer BM between the white sub-pixel and the transmissive area TA, thereby reducing the area where the light blocking layer BM is formed. As a result, the display panel 100 according to the embodiment of the present disclosure may improve transmittance. This light blocking layer BM may include a material that absorbs light, for example, black dye that absorbs all light in a visible light wavelength range. The light blocking layer BM may be referred to as a black matrix or BM.

The above-described color filter CF and light blocking layer BM are not provided in the transmissive area TA in order to maintain high light transmittance in the transmissive area TA.

The lower substrate 111 may be a plastic film, a glass substrate, or a silicon wafer substrate formed using a semiconductor process. The upper substrate 112 may be a plastic film, a glass substrate, or an encapsulation film. The lower substrate 111 and the upper substrate 112 may be formed of a transparent material. In some embodiments, the lower substrate 111 and the upper substrate 112 may be formed of a plastic material having flexibility. In some embodiments, the lower substrate 111 and the upper substrate 112 may be made of a flexible polymer film. For example, the flexible polymer film may be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS), and the present disclosure is not limited thereto. The lower substrate 111 may be formed to be larger than the upper substrate 112, so a portion of the lower substrate 111 may be exposed without being covered by the upper substrate 112.

As discussed above, the transparent display device 10 according to the embodiment of the present disclosure includes the transmissive area TA, which almost transmits incident light as it is, and the emission area EA, which emits light. As a result, in the embodiment of the present disclosure, objects or backgrounds located on the back surface or the front surface of the transparent display device 10 may be viewed through the transmissive areas TA of the transparent display device 10.

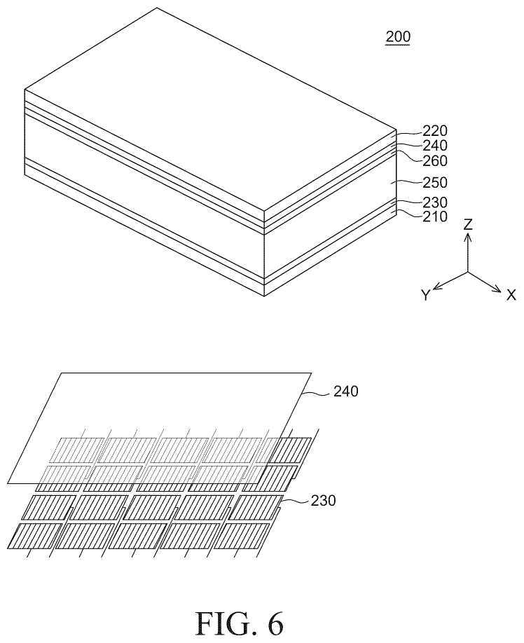

FIG. 6 is a perspective view of the light controlling panel according to an embodiment of the present disclosure.

Referring to FIG. 6, the light controlling panel 200 according to the embodiment of the present disclosure may be implemented in a transmissive mode that transmits incident light and a light blocking mode that blocks incident light. In an embodiment of the present disclosure, it may be assumed that the light blocking mode indicates a case where the light transmittance of the light controlling panel 200 is less than β%, and the transmissive mode indicates a case where the light transmittance of the light controlling panel 200 is α% or more. In this case, α may represent a value greater than β. The light transmittance of the light controlling panel 200 indicates a ratio of output light to light incident on the light controlling panel 200.

To this end, as illustrated in FIG. 6, the light controlling panel 200 according to the embodiment of the present disclosure includes a first substrate 210, a first electrode 230 disposed on the first substrate 210, a second substrate 220 facing the first substrate 210, a second electrode 240 disposed on the second substrate 220, and a dielectric layer 250 disposed between the first electrode 230 and the second electrode 240. The light controlling panel 200 may further include an adhesive layer 260 between the dielectric layer 250 and the second electrode 240.

Each of the first and second substrates 210 and 220 may be a glass substrate or a plastic film, but is not limited thereto. In some embodiments, the first and second substrates 210 and 220 may be formed of a plastic material having flexibility. In some embodiments, the first and second substrates 210 and 220 may be made of a flexible polymer film. For example, the flexible polymer film may be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS), and the present disclosure is not limited thereto.

As illustrated in FIG. 1, the light controlling panel 200 is disposed outside the transparent display panel 100, and may be provided in a separate configuration from the transparent display panel 100. In this case, the light controlling panel 200 may be formed in the film form and disposed on one surface of the transparent display panel 100 by a separate adhesive layer.

Although not illustrated in the drawing, in another embodiment of the present disclosure, the light controlling panel 200 may be disposed within the transparent display panel 100. In this case, the light controlling panel 200 may be disposed between the lower substrate 111 and the upper substrate 112 of the transparent display panel 100. In this case, the first substrate 210 and the second substrate 220 of the light controlling panel 200 may be omitted.

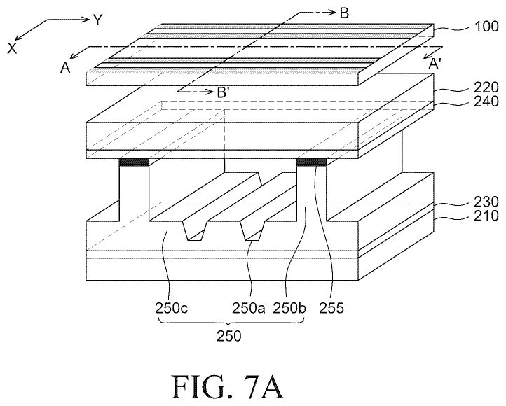

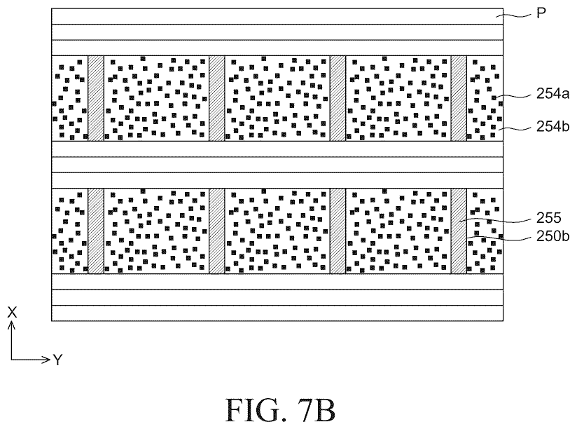

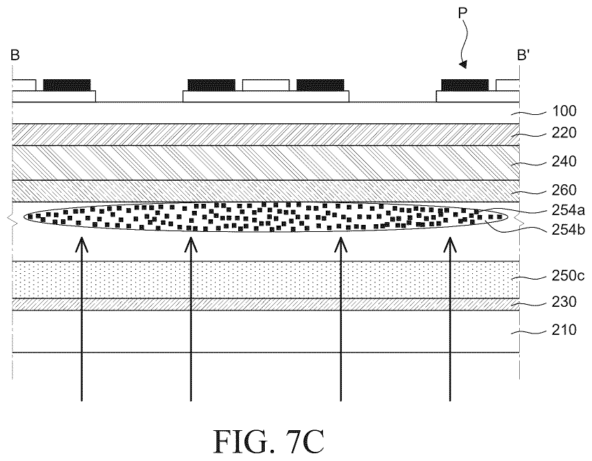

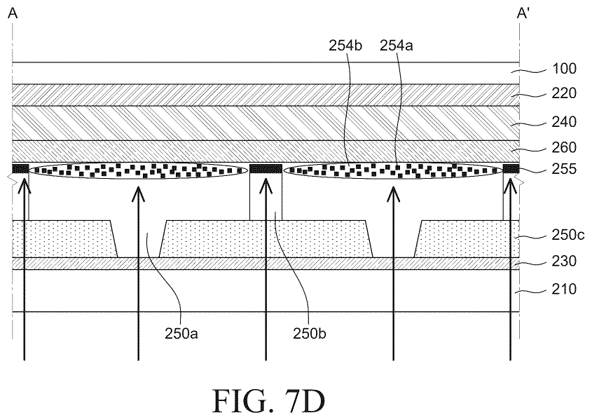

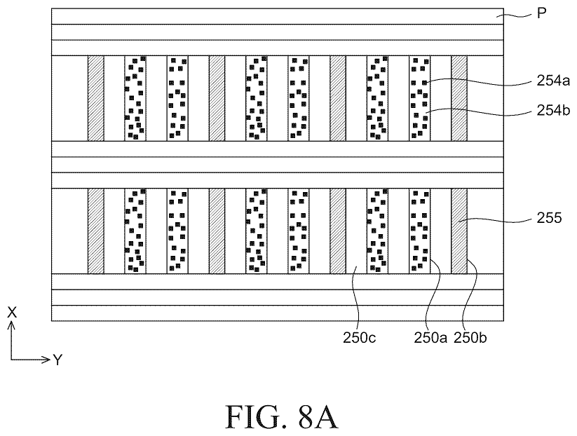

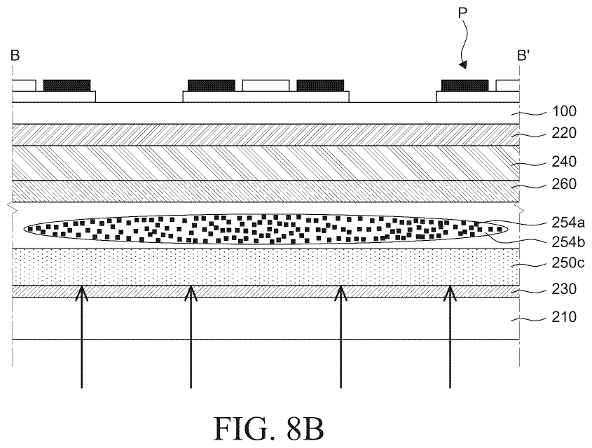

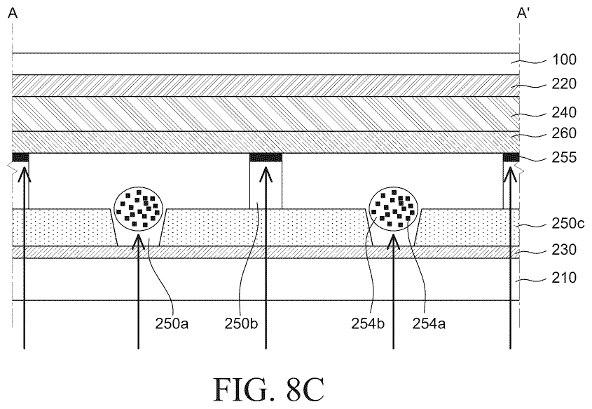

FIG. 7A illustrates a cross-sectional view of a light controlling panel according to an embodiment of the present disclosure. FIGS. 7B to 7D are cross-sectional views of the light controlling panel of FIG. 7A illustrating the light blocking mode according to the embodiment of the present disclosure. FIGS. 8A to 8C are cross-sectional views of the light controlling panel illustrating the light transmissive mode according to the embodiment of the present disclosure.

As illustrated in FIGS. 6 and 7A, the first electrode 230 may be provided on one surface of the first substrate 210 facing the second substrate 220, and the second electrode 240 may be provided on one surface of the second substrate 220 facing the first substrate 210. Each of the first electrode 230 and the second electrode 240 may be composed of a plurality of electrodes that overlap the entire transparent display panel 100. Specifically, the first electrode 230 may be divided into a plurality of unit electrodes and disposed to drive each unit electrode separately. By applying different magnitudes of voltage applied to each unit electrode, the transmittance may change for each area. The second electrode 240 may be formed as a common electrode.

The first electrode 230 and second electrodes 240 may be transparent electrodes including the transparent conductive materials. For example, the transparent conductive materials may include indium tin oxide (ITO) or indium zinc oxide (IZO) and the like, and the present disclosure is not limited thereto.

The dielectric layer 250 is disposed on one surface of the first electrode 230 facing the second electrode 240. The dielectric material may also be coated on a front surface of the second electrode 240. The dielectric layer 250 may be formed of a dielectric material having a first dielectric constant. The dielectric layer 250 includes a dielectric pattern 250c, a spacer 250b, and a groove 250a. The groove 250a is formed in a stripe shape at regular intervals in an X-axis direction, that is, in a direction perpendicular to the disposition direction of the pixels P, and is disposed to overlap both the emission area and the transmissive area. The spacer 250b is formed in the same direction as the extension direction of the groove 250a and overlaps both the emission area and the transmissive area.

Specifically, the spacer 250b may be formed so that a portion of a top surface of the dielectric pattern 250c protrudes toward the second electrode 240. In this case, a top surface of the spacer 250b may be flat. In addition, a light blocking layer 255 may be coated on the top surface of the spacer 250b. The light blocking layer 255 may be a black resin or black ink, but is not limited thereto.

As illustrated in FIGS. 7A to 8C, when the voltage is applied to the first electrode 230 and the second electrode 240, dielectric polarization may occur in the dielectric material of the dielectric pattern 250c, and a dielectric polarization density may vary depending on the shape of the top surface of the dielectric layer 250. Accordingly, the electric field may be formed strongest in the groove 250a of the dielectric pattern 250c.

Since a plurality of charged particles 254a move by the electric field generated between the first electrode 230 and the second electrode 240, when the voltage is applied to the first electrode 230 and the second electrode 240, the plurality of charged particles 254a may move to the groove 250a along the electric field as illustrated in FIG. 8C. Accordingly, when the voltage is applied to the first electrode 230 and the second electrode 240, the plurality of charged particles 254a may not be disposed in the area where the dielectric pattern 250c is disposed, and may have high light transmittance. Accordingly, when the voltage is applied to the first electrode 230 and the second electrode 240, external light may be transmitted through the area where the dielectric pattern 250c is disposed, so the light transmitted through the light controlling panel 200 may be incident on the transparent display panel 100.

When the light controlling panel 200 according to the embodiment of the present disclosure is in the transmissive mode, the plurality of charged particles 254a move to the groove 250a and may not remain in the area where the dielectric pattern 250c is disposed. In the light controlling panel 200 according to the embodiment of the present disclosure, the external light may be transmitted through the area where the plurality of charged particles 254a are not disposed, that is, the area where the dielectric pattern 250c is disposed. The light transmitting the light controlling panel 200 is incident on the transparent display panel 100 and may transmit the transparent display panel 100 through the transmissive area TA of the transparent display panel 100.

In this way, the external light may transmit the transparent display device 10 through the area where the groove 250a of the light controlling panel 200 is formed and the transmissive area TA of the transparent display panel 100. The transparent display device 10 according to the embodiment of the present disclosure may be disposed to overlap the groove 250a of the light controlling panel 200 with the non-transmissive area NTA of the transparent display panel 100 in order to have the high light transmittance in the transmissive mode.

One first electrode 230 or one second electrode 240 may be disposed to overlap the plurality of grooves 250a and the plurality of spacers 250b.

The spacer 250b may be disposed between the first electrode 230 and the second electrode 240 to maintain a gap between the first electrode 230 and the second electrode 240.

The spacer 250b may be disposed between dielectric patterns 250c disposed adjacently on a plane. A groove 250a may be disposed on at least one side of the spacer 250b.

The spacers 250b may be spaced apart from each other with the grooves 250a provided therebetween. In addition, the spacers 250b may be spaced apart from each other with the plurality of grooves 250a provided therebetween.

The plurality of charged particles 254a may be negatively or positively charged and distributed within the solvent 254b, and may block light incident from the outside. The plurality of charged particles 254a may be made of an electrophoresis material or a bistable ink.

The distributed area of the plurality of charged particles 254a may vary depending on the application of voltage to the first electrode 230 and the second electrode 240.

When a voltage opposite to the charge of the charged particle 254a is applied to the second electrode 240 as illustrated in FIGS. 7B to 7C, the charged particles 254a may be moved and distributed evenly toward the second substrate 220 where the second electrode 240 is formed. Since the light controlling panel 200 has the plurality of charged particles 254a distributed over the entire area where the second electrode 240 is provided, the external light may be blocked by the plurality of charged particles 254a in the entire area to implement the light blocking mode. The external light does not transmit the light controlling panel 200 and is not incident on not only the non-transmissive area NTA, but also on the transmissive area TA of the transparent display panel 100. When the charged particles 254a are a bistable ink, a material with the amount of charge is adsorbed onto particles, and an additive having a specific functional group is also added to the solvent 254b so that it has a certain amount of charge. In addition, even if the voltage applied to the first electrode 230 and the second electrode 240 is turned off, bi-stability is secured by an attractive force between the charged particles 254a and the solvent 254b, so the charged particles 254a may maintain their state for a long hold period and maintain the set transmittance level.

FIGS. 8A to 8C illustrate the charged particles 254a, the light controlling panel 200, and the display panel 100 in the transmissive mode according to the embodiment of the present disclosure. FIG. 8A is a front view of the display device in the transmissive mode, FIG. 8B is a cross-sectional view taken along line B-B′ of FIG. 7A in the transmissive mode, and FIG. 8C illustrates a cross-sectional view taken along line A-A′ of FIG. 7A in the transmissive mode.

When the voltage opposite to the charge of the charged particles 254a is applied to the first electrode 230, as illustrated in FIGS. 8A and 8B, the charged particles 254a move in the first electrode 230 along the electric field direction and are collected in a stripe shape inside a groove 250a. In this case, the external light may not transmit the area where the groove 250a is formed by the plurality of charged particles 254a and may be blocked. Therefore, the charged particles 254a may be visible in the form of a band in the transmissive area T, but a width of the groove 250a is sufficiently small compared to the transmissive area T, and thus, the groove 250a is not visible to a viewer.

Although not illustrated, in an embodiment of the present disclosure, the groove 250a may be disposed to overlap the non-transmissive area NTA of the transparent display panel 100. Moreover, the groove 250a of the light controlling panel 200 may be disposed so that at least a portion of the groove 250a overlaps the emission area of the transparent display panel 100. In addition, the groove 250a of the light controlling panel 200 may be disposed so that at least a portion of the groove 250a overlaps the transistor T of the transparent display panel 100. In addition, the groove 250a of the light controlling panel 200 may be disposed so that at least a portion of the groove 250a overlaps the color filter CF and the light blocking layer BM of the transparent display panel 100. As a result, it is possible to suppress the light transmittance from being lowered due to the charged particles 254a collected in the groove 250a during the transmissive mode.

The groove 250a may extend in one direction. In an embodiment of the present disclosure, the groove 250a may extend in the first direction (e.g., X-axis direction). As an example, the groove 250a may extend parallel to the first signal lines SL1. The groove 250a may be disposed to extend parallel to the spacer 250b in the area corresponding to the non-transmissive area NTA. For example, the groove 250a may be between two adjacent spacers and disposed to extend parallel to the spacer 250b in the area corresponding to the non-transmissive area NTA. For example, the groove 250a may be spaced from each of the two adjacent spacers by the same distance, but the present disclosure is not limited thereto, the groove 250a may also be spaced from the two adjacent spacers by the different distances.

The groove 250a has a first width W1, and the first width W1 may be smaller than the width of the dielectric pattern 250c, smaller than a distance between two adjacent spacers 250b, and smaller than the width of the non-transmissive area NTA of the transparent display panel 100 in the first direction (e.g., X-axis direction).

As a result, the light controlling panel 200 according to the embodiment of the present disclosure may suppress the grooves 250a from overlapping the transmissive area TA of the transparent display panel 100, and furthermore, suppress the light transmittance of the transparent display device 10 from being lowered due to the charged particles 254a collected in the groove 250a during the transmissive mode.

In an embodiment of the present disclosure, the dielectric pattern 250c, the spacer 250b, and the groove 250a included in the dielectric layer 250 may be integrally formed and may be formed of the same dielectric material. The dielectric pattern 250c, the spacer 250b, and the groove 250a included in the dielectric layer 250 may be formed simultaneously through an imprinting process. Accordingly, the manufacturing process costs may be reduced, the manufacturing process may be simple, the manufacturing process time may be shortened, and furthermore, the production energy may be reduced. In addition, since the light controlling panel 200 according to the embodiment of the present disclosure may reduce the manufacturing process, it is possible to reduce the greenhouse gases that may be generated during the manufacturing process and implement the environment/social/governance (ESG).

The adhesive layer 260 may be provided between the second electrode 240 and the dielectric layer 250 to adhere the dielectric layer 250 to the second electrode 240. The adhesive layer may be a transparent adhesive film such as optically clear adhesive (OCA) or a transparent adhesive such as optically clear resin (OCR). The adhesive layer 260 may also have a certain dielectric constant.

The light controlling panel 200 may be implemented in a film form, but is not limited thereto.

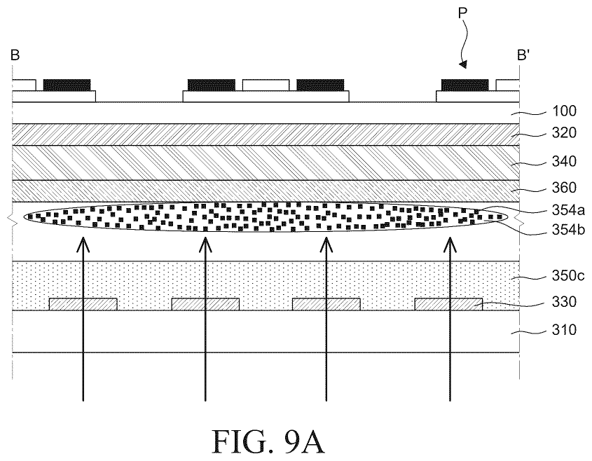

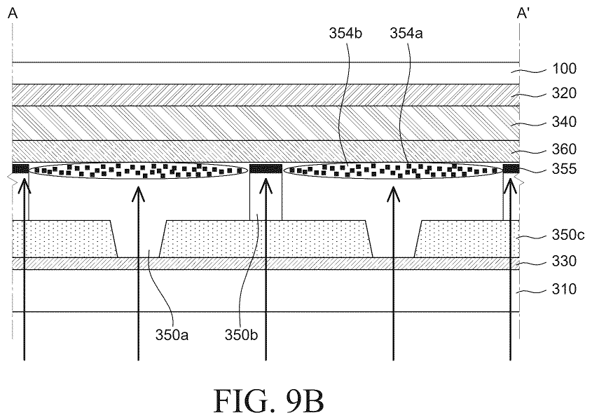

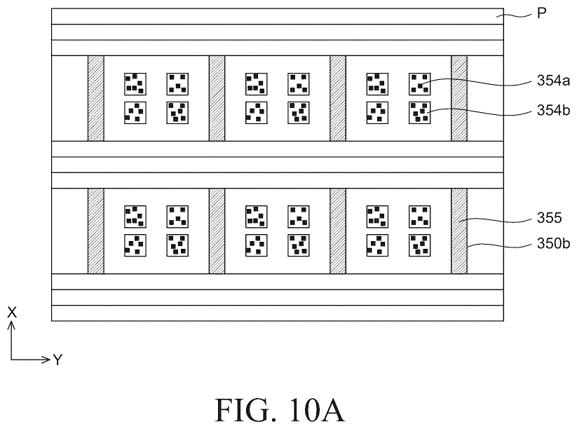

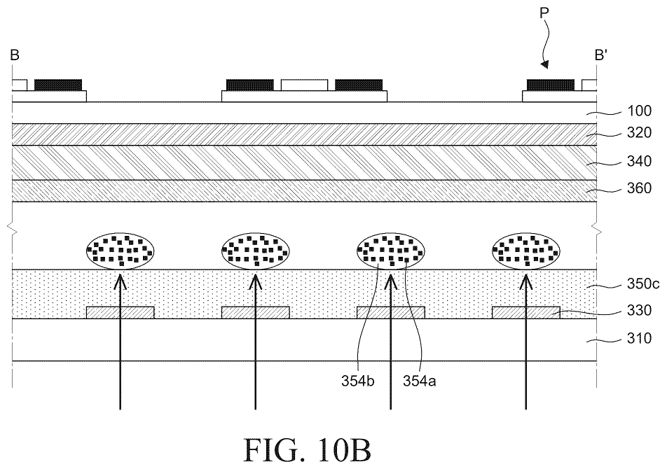

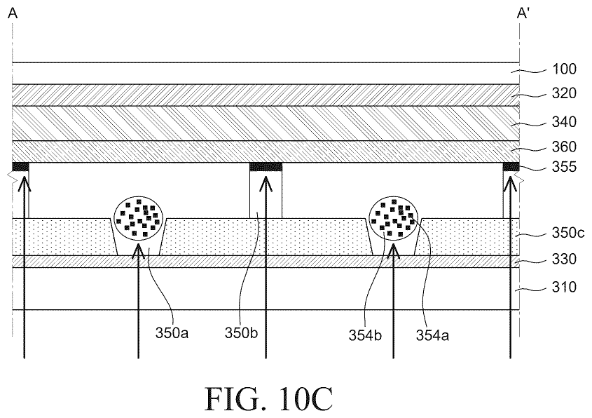

Hereinafter, the light controlling panel 200 according to the second embodiment of the present disclosure will be described with reference to FIGS. 9A and 9B and FIGS. 10A to 10C. Compared to the light controlling panel 200 according to the embodiment of the present disclosure illustrated in FIGS. 1 to 8C, the light controlling panel 200 according to the second embodiment of the present disclosure has substantially the same configuration except for a first electrode 330. Hereinafter, the differences will be described intensively and descriptions of substantially identical components will be omitted. The embodiments of the present disclosure described below may be applied in combination with or combined with the structure of the embodiment of the present disclosure illustrated in FIGS. 1 to 8C.

In FIG. 7A of the first embodiment of the present disclosure, the first electrode 230 is one bulk electrode, while in FIGS. 9A to 10C of another embodiment of the present disclosure, the first electrode 330 may be divided into a plurality of stripe patterns and formed in a direction that intersects the extension direction of the dielectric groove 350a.

That is, when the dielectric groove 350a is formed in the x-axis direction, the stripe-shaped first electrode 330 may be formed extending in the y-axis direction that intersects the x-axis direction. Accordingly, in the transmissive mode, the charged particles 354a is collected in the area where the groove 350a and the stripe-shaped first electrode 330 overlap, thereby further improving the light transmittance.

FIGS. 9A and 9B illustrate the charged particles 354a, the light controlling panel 200, and the display panel 100 in the light blocking mode according to an embodiment of the present disclosure.

When a voltage opposite to the charge of the charged particles 354a is applied to the stripe-shaped second electrode 340, the charged particles 354a may be moved and distributed evenly toward the second substrate 320 on which the second electrode 340 is formed, and may be dispersed. Since the light controlling panel 200 has the plurality of charged particles 354a distributed over the entire area where the second electrode 340 is provided, the external light may be blocked by the plurality of charged particles 354a in the entire area to implement the light blocking mode. The external light does not transmit the light controlling panel 200 and is not incident on not only the non-transmissive area NTA, but also on the transmissive area TA of the transparent display panel 100. When the charged particles 354a are a bistable ink, a material with the amount of charge is adsorbed onto particles, and an additive having a specific functional group is also added to the solvent 354b so that it has a certain amount of charge. In this case, even if the voltage applied to the stripe-shaped first electrode 330 and second electrode 240 is turned off, bi-stability is secured by an attractive force between the charged particles 354a and the solvent 354b, so the charged particles 254a may maintain their state for a long hold period and maintain the set transmittance level. A light blocking layer 355 may be further formed between the upper portion of the spacer 350b and the second electrode 340. In the light blocking mode, the light blocking layer 355 has the effect of suppressing the external light from being transmitted to the upper portion of the spacer 350b.

FIG. 10A is a front view of the display panel 100 and the light controlling panel 200 in the transmissive mode according to an embodiment of the present disclosure, FIG. 10B is a cross-sectional view taken along line B-B′ in the transmissive mode according to an embodiment of the present disclosure, and FIG. 10C illustrates a cross-sectional view taken along A-A′ in the transmissive mode according to an embodiment of the present disclosure.

As illustrated in FIGS. 10A to 10C, when the voltage opposite to the charge of the charged particles 354a is applied to the first electrode 330 in the transmissive mode, the charged particles 354a moves in the direction of the first electrode 330 along the electric field direction and is collected in an island shape inside the groove 350a or on the top surface of the first electrode 330. That is, the charged particles 354a may not be distributed throughout the stripe-shaped groove 350a, but may be distributed in the area where the first electrode 330 and the groove 350a intersect. For example, the charged particles 354a may be distributed only in the area where the first electrode 330 and the groove 350a intersect. In this case, the external light may not transmit the area where the first electrode 330 and the groove 350a are intersected by the plurality of charged particles 354a and may be blocked.

The groove 350a may extend in one direction. In an embodiment of the present disclosure, the groove 350a may extend in the first direction (e.g., X-axis direction). As an example, the groove 350a may extend parallel to the first signal lines SL1. The groove 350a may be disposed to extend parallel to the spacer 350b in the area corresponding to the non-transmissive area NTA. For example, the groove 350a may be between two adjacent spacers and disposed to extend parallel to the spacer 350b in the area corresponding to the non-transmissive area NTA. For example, the groove 350a may be spaced from each of the two adjacent spacers by the same distance, but the present disclosure is not limited thereto, the groove 350a may also be spaced from the two adjacent spacers by the different distances.

The groove 350a has a second width W2, and the second width W2 may be smaller than the width of the dielectric pattern 350c, smaller than the distance between two adjacent spacers, and smaller than a width of a transmitting unit. In addition, the second width W2 may be smaller than the width of the non-transmissive area NTA of the transparent display panel 100 in the first direction (e.g., X-axis direction).

As a result, the light controlling panel 200 according to the second embodiment of the present disclosure may suppress the grooves 350a from overlapping the transmissive area TA of the transparent display panel 100, and furthermore, suppress the light transmittance of the transparent display device 10 from being lowered due to the charged particles 354a collected in the groove 350a during the transmissive mode.

The external light transmitting the upper portion of the dielectric pattern 350c where the charged particles 354a are not distributed is incident on the display panel 100, and transmits the transmissive area of the display panel 100. Therefore, the charged particles 354a may be visible in the form of the island in the transmissive area T, but the width of the groove 350a is sufficiently small compared to the transmissive area T, and thus, the groove 250a is not visible to a viewer.

Although not illustrated, in the second embodiment of the present disclosure, the groove 350a may be disposed to overlap the non-transmissive area NTA of the transparent display panel 100. Moreover, the groove 350a of the light controlling panel 200 may be disposed so that at least a portion of the groove 350a overlaps the emission area of the transparent display panel 100. In addition, the groove 350a of the light controlling panel 200 may be disposed to partially overlap the transistor T of the transparent display panel 100. In addition, the groove 350a of the light controlling panel 200 may be disposed so that at least a portion of the groove 350a overlaps the color filter CF and the light blocking layer BM of the transparent display panel 100. As a result, it is possible to suppress the light transmittance from being lowered due to the charged particles 354a collected in the groove 250a during the transmissive mode.

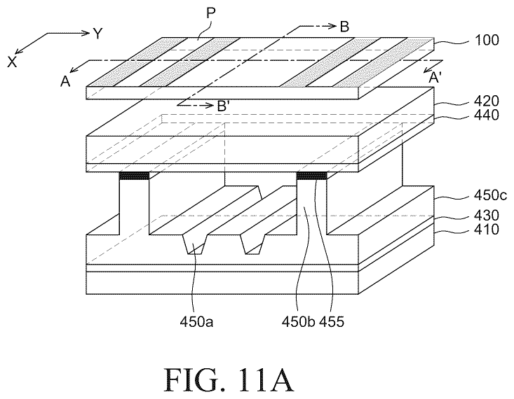

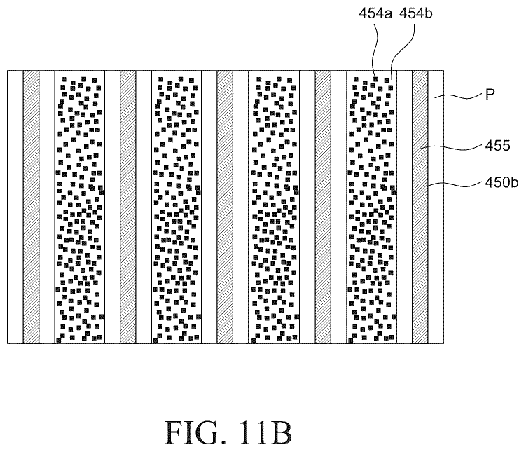

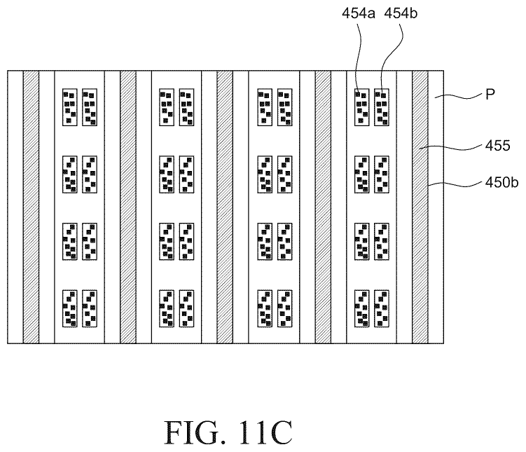

Hereinafter, the light controlling panel 200 according to the third embodiment of the present disclosure will be described with reference to FIGS. 11A to 11C. Compared to the light controlling panel 200 according to the second embodiment of the present disclosure illustrated in FIGS. 9A to 10C, the light controlling panel 200 according to the third embodiment of the present disclosure has substantially the same configuration except for the disposition direction. Hereinafter, the differences will be described intensively and descriptions of substantially identical components will be omitted. The embodiments of the present disclosure described below may be applied in combination with or combined with the structure of the embodiment of the present disclosure illustrated in FIGS. 1 to 10C.

When the pixel unit and the transparent part of the display panel 100 of the first and second embodiments of the present disclosure illustrated in FIG. 7A are disposed to extend in the Y-axis direction, the spacer 250b and the groove 250a of the light controlling panel 200 may be formed to extend in the X-axis direction orthogonal to the disposition direction of the pixel unit and the transmitting unit. Accordingly, an overlapping area may occur between the transmitting unit, the spacer 250b, and the groove 250a. On the other hand, the pixel unit and the transmitting unit of the display panel 100 of FIG. 11A according to the third embodiment of the present disclosure are disposed to extend along the X-axis direction, and a groove 450a and a spacer 450b are also formed to extend along the X-axis direction, which is the same as the disposition direction of the pixel unit and the transmitting unit. Furthermore, the spacer 450b of the third embodiment of the present disclosure may be disposed to overlap the pixel unit, that is, the light emitting unit, in the same direction.

FIG. 11B is a front view of the pixel unit and the light controlling panel 200 in the light blocking mode according to the third embodiment of the present disclosure. When the voltage opposite to the charge of the charged particles 454a is applied to the second electrode 440, the charged particles 454a may be moved and distributed evenly toward the second substrate 420 side on which the second electrode 440 is formed, and may be dispersed. Since the light controlling panel 200 has the plurality of charged particles 454a distributed over the entire area where the second electrode 440 is provided, the external light may be blocked by the plurality of charged particles 454a in the entire area to implement the light blocking mode. The external light does not transmit the light controlling panel 200 and is not incident on not only the non-transmissive area NTA, but also on the transmissive area TA of the transparent display panel 100. When the charged particles 454a are a bistable ink, a material with the amount of charge is adsorbed onto particles, and an additive having a specific functional group is also added to the solvent 454b so that it has a certain amount of charge. In this case, even if the voltage applied to the stripe-shaped first electrode 430 and second electrode 440 is turned off, the bi-stability is secured by an attractive force between the charged particles 454a and the solvent 454b, so the charged particles 454a may maintain their state for a long hold period and maintain the set transmittance level. The light blocking layer 455 may be further formed between the upper portion of the spacer 450b and the second electrode 440. In the light blocking mode, the light blocking layer 455 has the effect of suppressing the external light from being transmitted to the upper portion of the spacer 450b. As the spacer 450b and the pixel unit (non-transmitting unit) overlap and are disposed in the same direction, the spacer 450b is not visible in the screen display direction.

FIG. 11C is a front view of the pixel unit and the light controlling panel 200 in the transmissive mode according to the third embodiment of the present disclosure. When the voltage opposite to the charge of the charged particles 454a is applied to the first electrode 430 in the transmissive mode, the charged particles 454a moves in the direction of the first electrode 430 along the electric field direction and is collected in the island shape inside the groove 450a or on the top surface of the first electrode 430. That is, the charged particles 454a may not be distributed throughout the stripe-shaped groove 450a, but may be distributed in the area where the first electrode 430 and the groove 450a intersect. For example, the charged particles 454a may be distributed only in the area where the first electrode 430 and the groove 450a intersect. In this case, the external light may not transmit the area where the first electrode 430 and the groove 450a are intersected by the plurality of charged particles 454a and may be blocked.

The groove 450a may be disposed to extend parallel to the spacer 450b in the area corresponding to the non-transmissive area NTA. For example, the groove 450a may be between two adjacent spacers and disposed to extend parallel to the spacer 450b in the area corresponding to the non-transmissive area NTA. For example, the groove 450a may be spaced from each of the two adjacent spacers by the same distance, but the present disclosure is not limited thereto, the groove 350a may also be spaced from the two adjacent spacers by the different distances.

The groove 450a has a second width W2, and the second width W2 may be smaller than the width of the dielectric pattern 450c, smaller than the distance between two adjacent spacers, and smaller than the width of the transmitting unit. In addition, the second width W2 may be smaller than the width of the non-transmissive area NTA of the transparent display panel 100 in the first direction (e.g., x-axis direction).

As a result, the light controlling panel 200 according to the third embodiment of the present disclosure may suppress the grooves 450a from overlapping the transmissive area TA of the transparent display panel 100, and furthermore, suppress the light transmittance of the transparent display device 10 from being lowered due to the charged particles 454a collected in the groove 450a during the transmissive mode.

The external light transmitting the upper portion of the dielectric pattern 450c where the charged particles 454a are not distributed is incident on the display panel 100, and transmits the transmissive area of the display panel 100. Therefore, the charged particles 454a may be visible in the form of the island in the transmissive area T, but the width of the groove 450a is sufficiently small compared to the transmissive area T, and thus, the groove 450a is not visible to a viewer.

The light controlling panel 200 according to the third embodiment of the present disclosure may suppress the spacers 450b from overlapping the transmissive area TA of the transparent display panel 100, and furthermore, suppress the light transmittance of the transparent display device 10 from being lowered due to the charged particles 454a collected in the groove 450a during the transmissive mode.

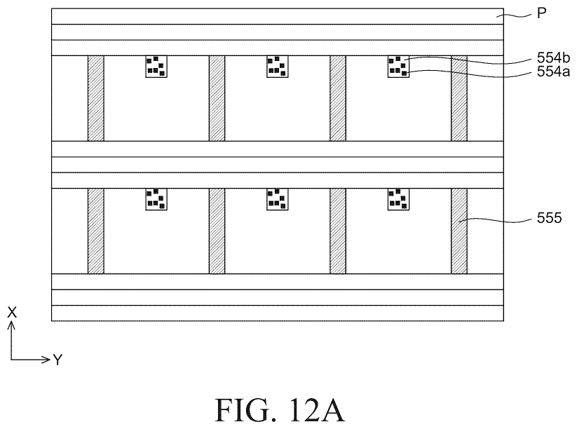

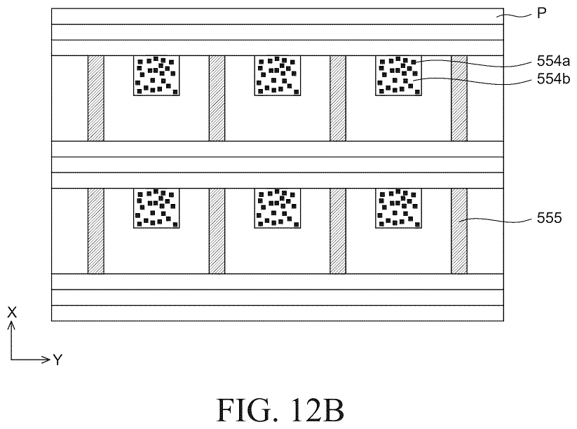

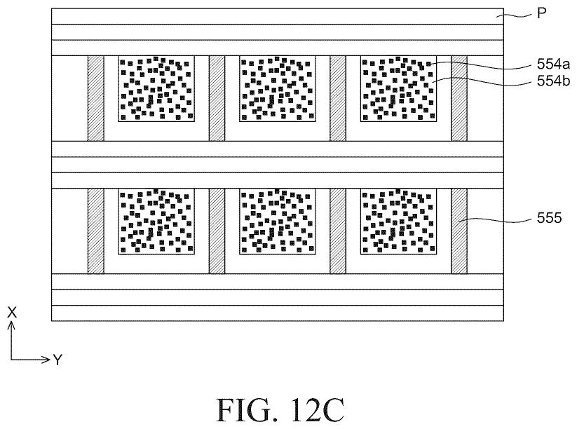

FIGS. 12A to 12C illustrate that the larger the voltage applied to the first electrode or the longer the time, the more the transmittance, and the smaller the applied voltage or the shorter the time the voltage is applied, the less the transmittance according to one or more embodiments of the present disclosure.

That is, as the voltage applied to the first electrode increases, the charged particles 554a become more concentrated in the groove, and as the applied voltage decreases, the force to collect the charged particles 554a into the groove becomes relatively small, so the charged particles 554a may be widely distributed in the groove. Therefore, as the applied voltage becomes smaller, the distribution area of the charged particles 554a may increase and the transmittance may decrease.

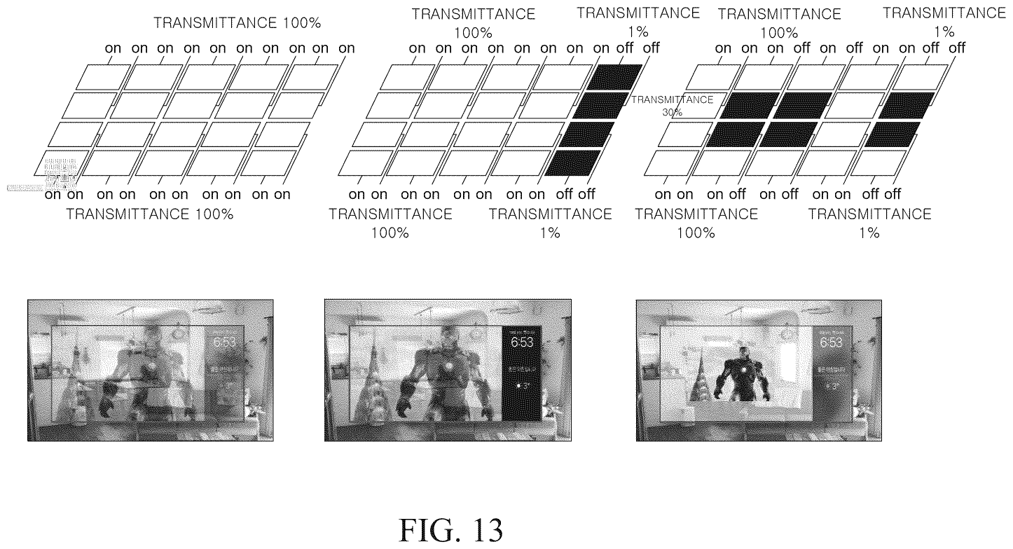

FIG. 13 illustrates an example of adjusting brightness to suit the external environment by applying the display panel 100 and the light control panel 200 according to one or more embodiments of the present disclosure. In other words, by simultaneously implementing the transmissive area and the shielding area on one screen, the light controlling panel 200 is divided and driven to suit the user's needs, thereby transmitting the image information tailored to the customer's needs and increasing the visibility of the transparent display device.

The embodiments of the present disclosure can also be described as follows:

According to embodiments of the present disclosure, the light controlling panel, comprises: a first electrode and a second electrode disposed to face each other; and a dielectric layer and charged particles provided between the first electrode and the second electrode, wherein the dielectric layer is provided with one or more grooves, and the dielectric layer has a dielectric pattern disposed between adjacent grooves and a plurality of spacers protruding toward the second electrode on a portion of a top surface of the dielectric pattern.

The first electrode is divided into a plurality of unit electrodes, and wherein each of the plurality of unit electrodes is driven separately.

The plurality of unit electrodes are applied with different magnitudes of voltage.

The second electrode is formed as a common electrode.

The spacer has a stripe shape extending in a first direction, and the groove has a stripe shape extending in the same direction as the spacer.

The spacer has a flat top surface, and a light blocking layer is coated on the top surface of the spacer.

The dielectric pattern, the spacer, and the groove are disposed integrally.

The groove is disposed between at least two of the plurality of spacers.

The first electrode and the second electrode are transparent electrodes, and the first electrode or the second electrode is disposed to overlap the one or more grooves.

The first electrode includes a plurality of block electrodes that are divided into a plurality of blocks and each block of the plurality of blocks being individually driven.

Each of the plurality of block electrodes of the first electrode includes a plurality of patterning electrodes in the patterned stripe shape.

The first electrode includes a plurality of patterning electrodes each having the patterned stripe shape.

The groove is disposed in a direction that intersects the plurality of patterning electrodes.

In a light transmissive mode, the charged particles are collected in an island or stripe shape on a patterning electrodes of the groove.

Even if a voltage is turned off at the first electrode and the second electrode, the charged particles remain in their state for a certain period of time to implement a light blocking mode or a transmissive mode.

According to embodiments of the present disclosure, the transparent display device, comprises: a transparent display panel including a transmissive area through which external light is transmitted and a non-transmissive area where a plurality of pixels are disposed; a first electrode and a second electrode disposed to face each other; and a dielectric layer and charged particles provided between the first electrode and the second electrode, wherein the dielectric layer is provided with one or more grooves, and wherein the dielectric layer has a dielectric pattern disposed between adjacent grooves and a plurality of spacers protruding toward the second electrode on a portion of a top surface of the dielectric pattern.

The first electrode is divided into a plurality of unit electrodes, and each of the plurality of unit electrodes is driven separately.

The plurality of unit electrodes are applied with different magnitudes of voltage.

The second electrode is formed as a common electrode.

The one or more grooves are disposed to overlap with the non-transmissive area of the transparent display panel.

The non-transmissive area includes an emission area in which a plurality of pixels are provided and emit light, and wherein, at least a portion of the one or more grooves are disposed to overlap with the emission area of the transparent display panel.

The spacer has a stripe shape extending in a first direction, and the groove has a stripe shape extending in the same direction as the spacer.

The spacer has a flat top surface, and a light blocking layer is coated on the top surface of the spacer.

The dielectric pattern, the spacer, and the groove are disposed integrally.

The groove is disposed between at least two of the plurality of spacers.

The first electrode and the second electrode are transparent electrodes, and the one first electrode or the one second electrode is disposed to overlap the one or more grooves.

The first electrode includes a plurality of block electrodes that are divided into a plurality of blocks and each block of the plurality of blocks being individually driven.

Each of the plurality of block electrodes of the first electrode includes a plurality of patterning electrodes in the patterned stripe shape.

The first electrode includes a plurality of patterning electrodes each having the patterned stripe shape.

The groove is disposed in a direction that intersects the plurality of patterning electrodes.

In a light transmissive mode, the charged particles are collected in an island or stripe shape on a patterning electrodes of the groove.

Even if a voltage is turned off at the first electrode and the second electrode, the charged particles remain in their state for a certain period of time to implement a light blocking mode or a transmissive mode.

The groove and the spacer are disposed in an area corresponding to the transmissive area.

The groove and the spacer are disposed in an area corresponding to the non-transmissive area.

The spacer is disposed to overlap the plurality of pixels in the non-transmissive area.

The spacer and the groove extend in the same direction as the disposition direction of the plurality of pixels in the non-transmissive area.

Although the embodiments of the present disclosure have been described in detail with reference to the accompanying drawings, the present disclosure is not limited thereto and may be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. All the technical concepts in the equivalent scope of the present disclosure should be construed as falling within the scope of the present disclosure.

What is claimed is:

1. A light controlling panel, comprising:
a first electrode and a second electrode that face each other; and
a dielectric layer and charged particles between the first electrode and the second electrode,
wherein the dielectric layer includes one or more grooves, and
the dielectric layer has a dielectric pattern between adjacent grooves of the one or more grooves and a plurality of spacers protruding toward the second electrode on a portion of a top surface of the dielectric pattern.

2. The light controlling panel of claim 1, wherein the first electrode is divided into a plurality of unit electrodes, and
wherein each of the plurality of unit electrodes is driven separately.

3. The light controlling panel of claim 2, wherein the plurality of unit electrodes are applied with different magnitudes of voltage.

4. The light controlling panel of claim 2, wherein the second electrode is formed as a common electrode.

5. The light controlling panel of claim 1, wherein:
a spacer of the plurality of spacers has a stripe shape extending in a first direction; and
a groove of the one or more grooves has a stripe shape extending in the first direction.

6. The light controlling panel of claim 1, wherein:
a spacer of the plurality of spacers has a top surface that is flat; and
a light blocking layer is coated on the top surface of the spacer.

7. The light controlling panel of claim 1, wherein the dielectric pattern, a spacer of the plurality of spacers, and a groove of the one or more grooves are integrally formed.

8. The light controlling panel of claim 1, wherein a groove of the one or more grooves is between at least two spacers of the plurality of spacers.

9. The light controlling panel of claim 1, wherein:
the first electrode and the second electrode are transparent electrodes; and
the first electrode or the second electrode overlaps the one or more grooves.

10. The light controlling panel of claim 1, wherein the first electrode comprises a plurality of block electrodes that are divided into a plurality of blocks, and each block of the plurality of blocks is individually driven.

11. The light controlling panel of claim 10, wherein each of the plurality of block electrodes of the first electrode includes a plurality of patterning electrodes having a patterned stripe shape.

12. The light controlling panel of claim 1, wherein the first electrode includes a plurality of patterning electrodes, each of the plurality of patterning electrodes having a patterned stripe shape.

13. The light controlling panel of claim 12, wherein a groove of the one or more grooves is in a direction that intersects the plurality of patterning electrodes.

14. The light controlling panel of claim 13, wherein, in a light transmissive mode of the light controlling panel, the charged particles are collected in an island or a stripe shape on the plurality of patterning electrodes of the groove.

15. The light controlling panel of claim 1, wherein responsive to a voltage being cut off at the first electrode and the second electrode, the charged particles remain in their state for a period of time and implement a light blocking mode or a transmissive mode of the light controlling panel.

16. A transparent display device, comprising:
a transparent display panel including a transmissive area through which external light is transmitted and a non-transmissive area that includes a plurality of pixels;
a first electrode and a second electrode that face each other; and
a dielectric layer and charged particles between the first electrode and the second electrode,
wherein the dielectric layer includes one or more grooves, and
the dielectric layer has a dielectric pattern between adjacent grooves of the one or more grooves and a plurality of spacers protruding toward the second electrode on a portion of a top surface of the dielectric pattern.

17. The transparent display device of claim 16, wherein the first electrode is divided into a plurality of unit electrodes, and
wherein each of the plurality of unit electrodes is driven separately.

18. The transparent display device of claim 17, wherein the plurality of unit electrodes are applied with different magnitudes of voltage.

19. The transparent display device of claim 17, wherein the second electrode is formed as a common electrode.

20. The transparent display device of claim 16, wherein the one or more grooves overlap with the non-transmissive area of the transparent display panel.

21. The transparent display device of claim 16, wherein the non-transmissive area incudes an emission area with the plurality of pixels that emit light, and
wherein, at least a portion of the one or more grooves overlap the emission area of the transparent display panel

22. The transparent display device of claim 16, wherein:
a spacer of the plurality of spacers has a stripe shape extending in a first direction; and
a groove of the one or more grooves has a stripe shape extending in the first direction.

23. The transparent display device of claim 16, wherein:
a spacer of the plurality of spacers has a top surface that is flat; and
a light blocking layer is coated on the top surface of the spacer.

24. The transparent display device of claim 16, wherein the dielectric pattern, a spacer of the plurality of spacers, and a groove of the one or more grooves are integrally formed.

25. The transparent display device of claim 16, wherein a groove of the one or more grooves is between at least two spacers of the plurality of spacers.

26. The transparent display device of claim 16, wherein:
the first electrode and the second electrode are transparent electrodes; and
the first electrode or the second electrode overlaps the one or more grooves.

27. The transparent display device of claim 16, wherein the first electrode comprises a plurality of block electrodes that are divided into a plurality of blocks, and each block of the plurality of blocks is individually driven.

28. The transparent display device of claim 27, wherein each of the plurality of block electrodes of the first electrode includes a plurality of patterning electrodes having a patterned stripe shape.

29. The transparent display device of claim 16, wherein the first electrode includes a plurality of patterning electrodes, each of the plurality of patterning electrodes having a patterned stripe shape.

30. The transparent display device of claim 29, wherein a groove of the one or more grooves is in a direction that intersects the plurality of patterning electrodes.

31. The transparent display device of claim 29, wherein, in a light transmissive mode of the transparent display device, the charged particles are collected in an island or a stripe shape on the plurality of patterning electrodes of a groove of the one or more grooves.

32. The transparent display device of claim 16, wherein responsive to a voltage being cut off at the first electrode and the second electrode, the charged particles remain in their state for a period of time and implement a light blocking mode or a transmissive mode of the transparent display device.

33. The transparent display device of claim 16, wherein a groove of the one or more grooves and a spacer of the plurality of spacers are in an area corresponding to the transmissive area.

34. The transparent display device of claim 16, wherein a groove of the one or more grooves and a spacer of the plurality of spacers are in an area corresponding to the non-transmissive area.

35. The transparent display device of claim 16, wherein a spacer of the plurality of spacers overlaps the plurality of pixels in the non-transmissive area.

36. The transparent display device of claim 16, wherein a spacer of the plurality of spacers and a groove of the one or more grooves extend in a direction that is same as a disposition direction of the plurality of pixels in the non-transmissive area.
